(19) United States
(12) Patent Application Publication
(10) Pub. No.: US 2006/0067454 A1
(43) Pub. Date: Mar. 30, 2006

(54) Circuit arrangement and method for determining a frequency drift in a phase locked loop

(76) Inventor: Andrea Camuffo, Munchen (DE)

Correspondence Address: ESCHWEILER & ASSOCIATES, LLC;NATIONAL CITY BANK BUILDING, 629 EUCLID AVE., SUITE 1210, CLEVELAND, OH, 44114, US

(21) Appl. No.: 11/234,686

(22) Filed: Sep. 23, 2005

(30) Foreign Application Priority Data
Sep. 24, 2004 (DE) 10 2004 046 404.9

(51) Int. Cl. H03D 3/24

(52) U.S. Cl. 375/376

(57) ABSTRACT

A circuit arrangement for determining a frequency drift in a phase locked loop includes a type I phase locked loop having a phase comparator, a charge pump, a loop filter, an oscillator and also a frequency divider in a feedback path of the control loop. A device is coupled to the phase locked loop for the purpose of determining a pulse length of the actuating voltage signal at at least two different times during an operation of the control loop. Furthermore, a computing unit is connected to an output of the device. It is designed for forming a difference between the pulse lengths at the at least two different times, as a result of which a phase and frequency drift of an output signal of the control loop can be determined.

### REFERENCE TO RELATED APPLICATIONS

This application claims the benefit of the priority date of German application DE 10 2004 046 404.9, filed on Sep. 24, 2004, the contents of which are herein incorporated by reference in their entirety.

### FIELD OF THE INVENTION

The invention relates to a circuit arrangement for determining a frequency drift of an output signal in a phase locked loop. The invention furthermore relates to a method for determining a frequency drift in a phase locked loop.

### BACKGROUND OF THE INVENTION

Phase locked loops are usually used for generating frequency-stable signals. The signals provided serve for example as a local oscillator signal in a transmission path of a mobile communication device.

Depending on the mobile communication standard used, it is also possible, however, to embody phase locked loops for a direct modulation, in which the output signal of an oscillator of the control loop is modulated directly. This is expedient primarily in the case of mobile communication standards which use a pure frequency modulation. One example of such a standard is the GSM mobile radio standard.

Phase-locked loops which have a frequency divider embodied in a feedback path of the control loop with a sigma-delta modulator have generally proved to be advantageous. These modulators are programmable and are also referred to as multi-modulus dividers. A frequency modulation of the output signal of the control loop is effected by modulation of the divider ratio of the frequency divider in the feedback path.

This solution has the disadvantage, however, that the frequency information has to be transferred through the loop filter of the phase locked loop. A normal loop filter generates errors in the modulation, however, as a result of its transfer response. In order to reduce the influence of the bandwidth of the loop filter on the modulated signal, it may be expedient to use a type I phase locked loop. This is distinguished by a nonintegrating loop filter, as a result of which a significantly smaller area is required for the capacitances. As a result, the outlay for integration in a semiconductor body is also reduced, and costs and space are saved.

The disadvantage of a type I phase locked loop with a nonintegrating loop filter consists, however, in the fact that in the event of frequency changes or rapidly changing actuating signals at an actuating input of the frequency divider, an additional phase and frequency error is generated in the output signal. This error is manifested in a temporally falling frequency and phase drift.

In order to compensate for the frequency and phase error, time-dependent additional modulation information is usually fed to the control loop. This leads to a predistortion of the signal. Random external parameter changes, for example of the temperature, but also aging effects and component variations have an influence on the phase locked loop and thus on the phase and frequency error, which cannot be compensated for by a fixedly programmed value.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

In accordance with one aspect of the present invention, a circuit arrangement for determining a frequency drift in a phase locked loop which can take account of the abovementioned random parameters in the behavior of a control loop is described. Furthermore, the invention also includes a method for determining a frequency drift in a control loop which enables a simple correction.

The arrangement is achieved by means of a circuit arrangement comprising a type I phase locked loop having a reference signal input and a signal output for providing a signal. The type I phase locked loop has a phase comparator having a reference input connected to the first input. Furthermore, the phase comparator contains a feedback input and an actuating output for outputting an actuating signal, which is can be embodied as a pulsed actuating signal. Coupled to the actuating output is a charge pump for providing a voltage signal depending on the actuating signal. Furthermore, a loop filter is provided, the input of which is coupled to the output of the charge pump and the output of which is coupled to an actuating input of a voltage controlled oscillator. A signal output of the oscillator forms the signal output of the phase locked loop and is connected via a frequency divider to the feedback input of the phase comparator.

In accordance with the principle proposed, a device is furthermore provided, which is designed for determining a pulse length of the actuating or voltage signal at at least two different times during an operation of the phase locked loop. A computing unit is connected to an output of the device, for forming a difference between the pulse lengths at the at least two different times.

By determining the duration of a voltage signal or an actuating signal, the circuit arrangement according to the invention directly permits a statement about a frequency or phase drift of the voltage controlled oscillator. This is possible since a frequency drift from the control loop is translated directly into a variation of the actuating signal of the phase comparator. By means of the at least two different measurements at different times, the drift can be ascertained by the connected computer unit. The circuit arrangement according to the invention makes it possible to calibrate and also to ascertain and to compensate for the drift of the type I phase locked loop during operation as well.

The device, in one example, can be designed as a counter with a counting input, the counting input being coupled to the output of the oscillator. In this configuration, the time duration of the actuating signal or the voltage signal of the charge pump is accordingly ascertained by means of a counting operation with regard to the clock cycles of the output signal of the oscillator. The clock period of the output signal is dependent on the voltage signal of the charge pump that is applied to the actuating input of the oscillator. Consequently, in one design of the invention, the device is designed as a counter for a counting operation that ascertains the clock cycles of the output signal for a specific period of time at two different times.

A circuit can be connected upstream of the counting input of the device, said circuit being designed for changing a plurality of the output signal of the oscillator depending on a control signal. This increases the accuracy of the measurement and avoids systematic errors occurring during the measurement, in particular. In another refinement, this circuit is formed with a logic XOR gate (non-equivalence gate), a first input of the XOR gate being connected to the signal output of the oscillator. The control signal is present at the second input.

The device can, in another example, comprise a shift register, which is coupled to the output of the phase comparator on the input side. This shift register serves for repeated measurement of the time duration or for repeated counting of the clock periods of the output signal of the oscillator. By repeating the measurement, the drift can be determined significantly more accurately. The shift register, as an example, comprises a number of feedback flip-flops connected in series. In one development of the invention, provision is made of a tap at a data output of the first flip-flop of the shift register, which is embodied for outputting the control signal and is connected to the second input of the circuit or to an input of the XOR gate. As a result, with each actuating signal of the phase comparator of the charge pump, the polarity of the output signal is reversed at the input of the device, as a result of which the accuracy is increased.

If a deviation of the duty cycle on account of the drift is small with respect to a reference frequency of a reference signal, it is expedient, in accordance with one aspect of the invention, for in each case one frequency divider to be connected upstream of the reference input and the feedback input of the control loop. As a result, both the reference frequency of the reference signal and the frequency of the fed-back oscillator signal are reduced, thereby increasing the time in which the charge pump outputs an actuating signal. At the same time, the duty cycle remains constant. The frequency dividers are can be of programmable design.

In another example, the device comprises an activating input for feeding in a pulsed activation signal. The device is can be designed for a measurement of the time duration while the activation signal is present. In one embodiment, the activation signal is embodied by a clock edge of a reference signal and a clock edge of a fed-back and frequency-divided output signal.

In accordance with another aspect of the invention, a method for determing frequency drift in a phase locked loop is disclosed. A phase locked loop is provided having a charge pump for setting a voltage controlled oscillator. A reference signal is fed in. The output signal of the oscillator is compared with the reference signal. A pulsed control signal is generated with a duty cycle for setting the charge pump. A first time duration is measured of the actuating signal or a voltage signal generated by the charge pump of the control loop, at a first instant. A second time duration is measured of the actuating signal or a voltage signal generated by the charge pump of the control loop, at a second instant subsequent to the first instant. The frequency drift of the phase locked loop is determined by forming a difference between the first time duration and the second time duration.

The method according to the invention accordingly determines the duration of the actuating signal of the phase comparator of a type I control loop or the voltage signal of the charge pump of the control loop at a first instant and a second instant. Since an actuating signal in a type I phase locked loop directly influences the output frequency of the voltage controlled oscillator, it is thus possible to determine a frequency drift of the output signal by forming a difference between the first and the second time duration. This method can also be employed during an operation of a phase locked loop. The method can be used in a type I phase locked loop that is embodied for a direct modulation of an output signal.

In one exemplary development of the method, the measuring step contains the step of ascertaining a number of clock cycles of the output signal of the oscillator. It is expedient to measure the number of clock cycles when a signal is output by the charge pump or the phase comparator. Accordingly, a pulsed control signal is can be generated.

In one example, measuring the duration comprises ascertaining a clock edge of the reference signal and ascertaining a clock edge of the output signal of the oscillator. The, a number of clock cycles of the output signal of the oscillator are ascertained during an occurrence of a clock edge of the reference signal up to the occurrence of a clock edge of the output signal. This refinement of the invention involves measuring the number of clock cycles which are dependent on a frequency or a phase drift of the output signal of the oscillator.

In another development of the invention, for the step of feeding in a reference signal, a frequency of the reference signal is divided by a predetermined divider factor and a frequency of the output signal of the oscillator is divided by the predetermined divider factor. As a result, the frequency of the reference signal and of the output signal is reduced, thereby increasing the length of the pulsed control signal output by the phase comparator, while the duty cycle remains constant. In this refinement of the method according to the invention, a frequency drift of an output signal of an oscillator can be determined even at very high output frequencies of the oscillator signal.

The following description and annexed drawings set forth in detail certain illustrative aspects and implementations of the invention. These are indicative of but a few of the various ways in which the principles of the invention may be employed.

### BRIEF DESCRIPTION OF THE DRAWINGS

The invention will now be explained in detail on the basis of exemplary embodiments with the aid of the drawings.

FIG. 1 shows a first exemplary aspect of the invention.

FIG. 2 shows a second exemplary aspect of the invention.

FIG. 3 shows a configuration of a shift register in accordance with the aspect in FIG. 2.

FIG. 4 shows a timing diagram with various signals in accordance with the aspect in FIG. 2

FIG. 5 shows an exemplary aspect of the method according to the invention.

### DETAILED DESCRIPTION OF THE INVENTION

One or more implementations of the present invention will now be described with reference to the attached drawings, wherein like reference numerals are used to refer to like elements throughout, and wherein the illustrated structures are not necessarily drawn to scale.

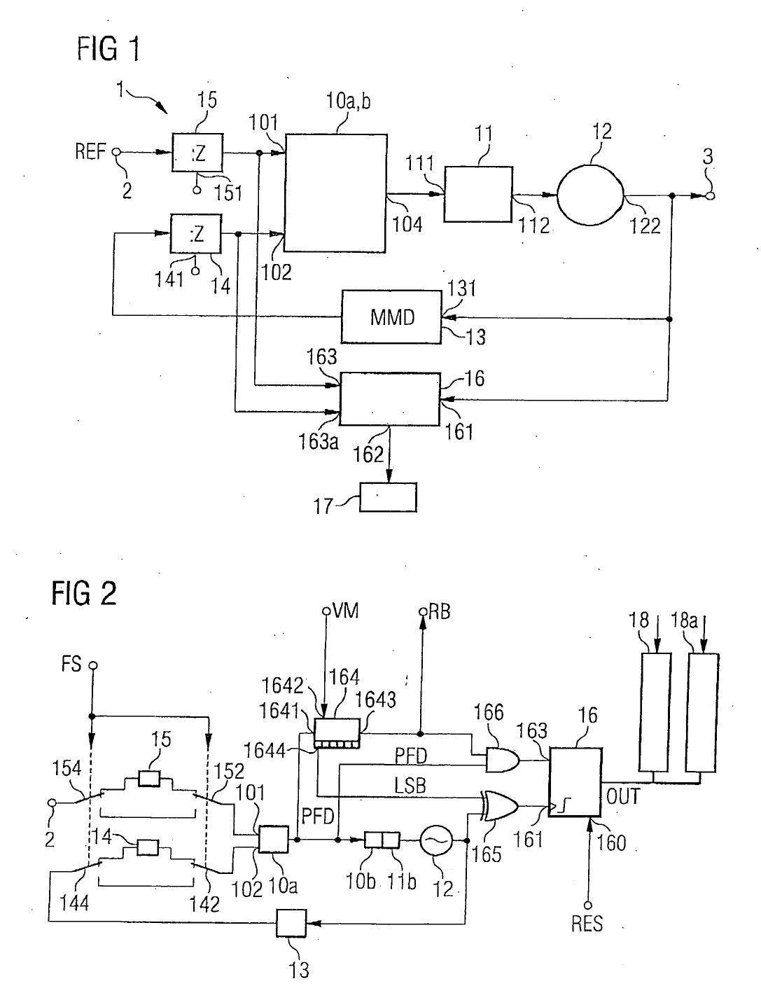

FIG. 1 shows a circuit arrangement according to the invention in a first aspect or embodiment. The phase locked loop 1—illustrated therein—with the measuring and computing unit provided for determining a frequency and phase drift of the output signal of the oscillator can be used in mobile radio devices or mobile communication systems.

The aspect or embodiment illustrated in FIG. 1 comprises a signal input 2, to which a reference signal REF is fed, and also a signal output 3, at which a frequency-stable output signal can be tapped off. In accordance with the principle proposed, a phase comparator 10a, which is illustrated here together with a charge pump 10b, is connected to a loop filter 11 on the output side. The output 112 of the loop filter 11 is connected to an actuating input of a voltage controlled oscillator 12. On the output side, the oscillator forms the signal output 3 of the control loop. Furthermore, the signal output 122 of the oscillator 12 is connected to an input 131 of a multi-modulus divider 13. The output of the multi-modulus divider 13 is in turn coupled to a feedback input 102 of the phase comparator 10a.

The multi-modulus divider 13 makes it possible to set an arbitrary divider ratio in the feedback path of the phase locked loop and, consequently, to control the output frequency of the oscillator 12. In this case, a specific divider ratio is set with the multi-modulus divider 13. The signal output by the voltage controlled oscillator 12 is divided in this divider ratio and a signal having the divided frequency is fed to the input 102 of the phase comparator 10a. At the same time, the reference signal REF is present at the reference input 101 of the phase comparator 10a. If the phases of the reference signal REF and of the fed-back divided signal do not match, then the phase comparator outputs to the charge pump 10b a pulsed actuating signal proportional to the deviation. The pulse length of the actuating signal and thus also the duty cycle are a measure of the deviation. The charge pump 10b generates a voltage signal which is output at the output 104 and is applied via the loop filter 11 to the actuating input of the voltage controlled oscillator 12.

The frequency of an output signal of the voltage controlled oscillator 12 is changed by an actuating signal from the charge pump 11 until the phases of the fed-back signal and of the reference signal match and the phase comparator no longer generates a signal. By altering the frequency divider ratio in the multi-modulus divider 13, it is possible, therefore, to directly modulate the output frequency of the voltage controlled oscillator by altering the divider ratio.

In order to reduce the influence of the control loop on the modulation, the loop filter 11 is embodied as a nonintegrating loop filter. This type of control loops whose loop filter comprises a nonintegrating structure are referred to as type I phase locked loops.

The output frequency of the voltage controlled oscillator in a type I phase locked loop as a function of time can be expressed by the equation specified below.
f_{VCO}(t)=f₀+K_{VCO}*ν(t)+Drift*e⁻(t/τ)

In this case, f₀ designates the output frequency of the voltage controlled oscillator if no voltage signal is present at the actuating input. It is evident that the output frequency f₀ of the voltage controlled oscillator is dependent on a drift subject to an exponentially falling regularity.

The phase locked loop then attempts, by means of suitable actuating signals to set the output frequency of the voltage controlled oscillator such that the phases between the divided output signal and the reference signal match. In type I phase locked loops, the average actuating signal is determined only by the duty cycle of the phase comparator 10a and of the charge pump 10b. The pulse output by the phase comparator in turn defines the duty cycle, so that the terms are used synonymously hereinafter. By way of example, in the case of a duty cycle of 1/1 the pulse length is twice as long as in the case of a duty cycle of 1/4.

Disregarding the influence of the filter bandwidth of the loop filter, it emerges that the input voltage ν(t) at the voltage controlled oscillator is a direct linear function of the duty cycle Tv of the actuating signal of the phase comparator. It emerges that:
ν(t)=Tv(t)*I₀*Rp
where I₀ represents a constant current of the charge pump and Rp represents the resistance of the loop filter.

The result is a duty cycle which is proportional to the frequency:
Tv(t)=[f_{VCO}(t)−f₀−Drift*e^{-(t/τ)}]/(K_{VCO}*I₀*Rp)

A drift of the control loop can be ascertained by twice determining the duty cycle Tv at different instants. Consequently, the pulse length is determined at two different instants.

In the present arrangement in accordance with FIG. 1, a device 16 is provided which is designed as a counter. Its counting input 161 is connected to the output of the voltage controlled oscillator 12. Furthermore, it contains a first input terminal 163 and also a second input terminal 163a. The input 163 is connected to the reference input 101 of the phase comparator 10; the input 163a is connected to the feedback input 102. The counter 16 then measures the number of clock periods of an output signal of the voltage controlled oscillator 12.

For this purpose, it uses the rising clock edge of the reference signal REF and also the rising clock edge of the signal that is divided by the multi-modulus divider 13 and fed back. Upon the occurrence of a rising clock edge of the reference signal, the counter 16 starts to determine the number of periods. Upon a subsequent occurrence of a rising clock edge in the fed-back signal, the counting operation is stopped again.

This step is repeated at two different instants. This results in two different numbers of clock cycles which are directly proportional to the duty cycle and thus to the pulse length of the actuating signal at the output of the phase comparator at the two instants. These are output at the output of the counter 162 and converted into a drift by the computer unit 17.

In practice, the deviation of the duty cycle and thus the frequency error on account of the drift is only very small and in the region of 0.1% of the output frequency of the oscillator. At very high frequencies of the reference and fed-back signals, the temporal shift between the occurrence of the two clock edges is accordingly very small. As a result, the length of the pulse in the actuating signal is also only very short, thereby making it more difficult to measure the number of clock periods of the output signal of the oscillator.

Therefore, two additional frequency dividers 14 and 15 are provided. The frequency divider 14 is connected between the output of the multi-modulus divider 13 and the input 102. The frequency divider 15 is arranged between the input 2 and the feedback input 101 of the phase comparator. The two frequency dividers 14 and 15 have the same divider ratio in each case. As a result of the additional division, the time duration in which the charge pump outputs a pulse is lengthened. The counter 16 thus acquires additional time for a counting operation.

If, by way of example, the drift lies in the region of 0.1% of the output frequency of the oscillator, the time difference is in the region of 50 ps at a reference frequency of 26 MHz. Even at an output frequency of the voltage controlled oscillator of approximately 4 GHz, this time period is too small to be measured by the counter 16 since just a clock period of the output signal amounts to approximately 250 ps. By means of the two additional frequency dividers, which, by way of example, additionally divide the frequency of the reference signal and also the frequency of the divided output signal by the factor 32, the time shift also increases from 50 ps to 1.6 ns. The counter can then detect a plurality of clock periods. As a result, the difference between the two counting operations also becomes large enough such that the computing unit connected downstream can ascertain a drift.

In this configuration, for the determination of the drift, accordingly, firstly the phase locked loop is activated and the multi-modulus divider 13 is programmed correspondingly. By way of example, it is programmed to divide the frequency of the voltage controlled oscillator of 4004 MHz present on the input side by the factor 154. After a time of 20 μs after activation of the control loop, the two dividers 14 and 15 are activated in order to divide the reference signal and also the fed-back signal by the factor 32. The time duration of 20 μs is necessary in order to give the capacitances of the loop filter sufficient time for charging. After approximately 400 μs, the phase locked loop has settled, but still has an exponentially falling drift.

Then, for example upon a rising clock edge of the reference signal, a measurement is begun and the counter 16 ascertains the number of clock cycles of the output signal of the voltage controlled oscillator 12 up to the occurrence of a clock edge in the fed-back signal. This value is buffer-stored.

After approximately 1 ms, a frequency and phase drift in the output signal of the oscillator have almost completely disappeared on account of the exponential fall in the drift. The counter 16 then once again ascertains the number of periods of the output signal of the voltage controlled oscillator after the occurrence of a rising clock edge in the reference signal. The counting operation is stopped as soon as a rising clock edge in the fed-back signal is present at the input 163a of the counter 16. The difference between the two measurements is directly proportional to the drift.

It is expedient to repeat the number of counting operations and, if appropriate, to form an average of the results. It may likewise be expedient to slightly shift the temporal beginning of the counting by means of a slight disturbance of the start signal at the input 163. Systematic errors are thereby reduced. The disturbance should expediently be embodied as additionally added noise or as jitter and have at most the magnitude of the oscillator period.

FIG. 2 shows a further exemplary aspect or embodiment. Operationally or functionally identical components bear the same reference symbols in this case. The phase locked loop in accordance with the exemplary embodiment of FIG. 2 is constructed in a similar manner to the phase locked loop 1 of FIG. 1.

On the output side, a voltage controlled oscillator 12 is connected to the multi-modulus divider 13. The multi-modulus divider 13 divides the signal output by the voltage controlled oscillator 12 in terms of its frequency and feeds it to the phase detector 10a of the control loop. In this exemplary embodiment, the additional frequency divider 14 is connected in parallel with a line between the switches 144 and 142. The switches 144 and 142 thus serve for selecting whether the frequency-divided signal is passed directly to the feedback inputs of the phase detector 10a or via the frequency divider 14 to the input 102 of the phase detector 10a. The reference input 2 is also coupled to the reference input 101 of the phase detector 10a in the same way. Here the switches 154 and 152 bridge the frequency divider 15.

The switch position is prescribed by a control signal FS. The additional frequency division is only carried out during a calibration operating mode. In a normal operating mode, the switches 142, 144 and 152, 154 bridge the additional frequency dividers 14 and 15.

The phase detector 10a outputs an actuating signal PFD for setting the charge pump 10b. The actuating signal PFD is formed by a pulsed signal, the pulse length being directly proportional to the phase difference between the reference signal and the fed-back signal. The actuating signal PFD accordingly becomes longer, the greater the phase difference between the two signals present at the inputs 101 and 102. The duty cycle or the on/off ratio of the actuating signal also changes owing to the pulse length change of the actuating signal PFD. Accordingly, the charge pump 10b also generates a correspondingly longer or stronger voltage signal for setting the voltage controlled oscillator. In type I phase locked loops, the length of the pulse of the actuating signal PFD and thus the duty cycle is directly proportional to the frequency change of the output signal of the oscillator.

On the output side, the voltage controlled oscillator 12 is coupled to the input of an XOR gate 165 (Exclusive-OR Gate, non-equivalence gate), the output of which is connected to the clock input 161 of a counter 16. The counter 16 furthermore contains a reset input 160, to which the reset signal RES is fed to reset the counter. It furthermore contains a data input 163, which is likewise connected to the output of a logic AND gate 166. The logic AND gate 166 serves for activating the counter only during the pulse of the actuating signal PFD and for counting the clock periods of the output signal of the voltage controlled oscillator. For this purpose, the logic AND gate 166 is connected by a first input directly to the output of the phase detector 10a. A second input carries the signal RB, and is connected to the output 1643 of a shift register 164. The input 1641 of the shift register 164 is connected to the output of the phase detector 10a. The shift register 164 serves for multiply carrying out the counting operation with regard to the clock cycles of the output signal of the voltage controlled oscillator during a pulse length. The length of the register determines the number of repetitions.

At the same time, the lowest value of the shift register, the LSB (least significant bit), at the output 1644, is fed to the second input of the XOR gate 165. As a result, the polarity of the output signal of the XOR gate is inverted after each actuating pulse of the actuating signal PFD. A systematic error is thereby reduced and the accuracy of the counting operation is increased.

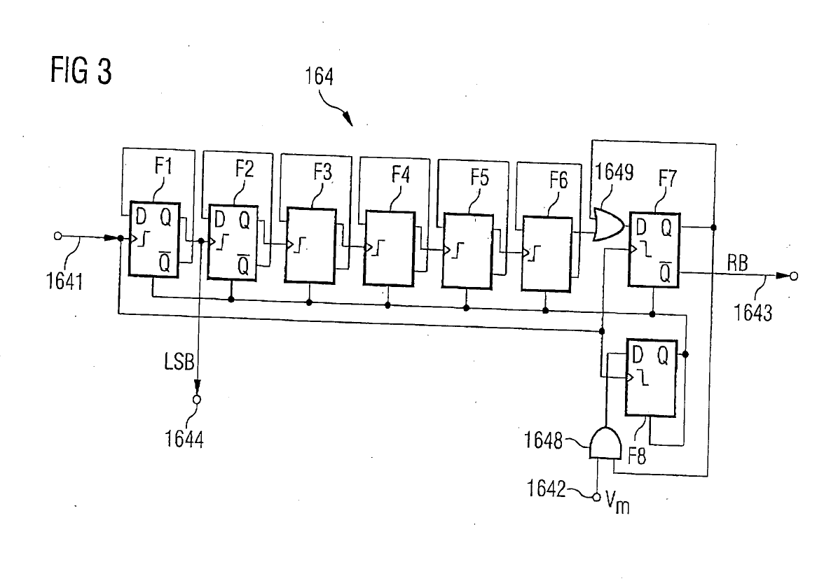

FIG. 3 shows an exemplary aspect or embodiment of such a shift register 164. The latter contains a number of cascaded flip-flop circuits F1 to F8. In the case of each of these flip-flop circuits, the inverted data output Q′ is fed back to the data input D of the respective flip-flop. The data output Q is connected to the clock input of the next flip-flop. The flip-flop circuits F1 to F6 are positively edge-triggered. Upon each positive clock edge, they output the signal present at their data input D to their data output Q. The actuating signal input 1641, at which the actuating signal PFD is present, is connected to the clock input of the first flip-flop F1.

Two additional, negatively edge-triggered flip-flops F7 and F8 are furthermore provided. These serve for resetting the entire circuit, the integration illustrated ensuring that the output 1643 of the shift register 164 remains active and at a logic high state for 64 clock pulses of the actuating signal PFD. For this purpose, the inverted output Q′ of the edge-triggered flip-flop F7 is connected to the output 1643. The data output Q of the flip-flop F7 is connected to the data input D of the flip-flop F7 via a logic OR gate 1649. The second input of the logic OR gate 1649 is connected to the data output Q of the last series flip-flop F6. The flip-flop F8 serves for resetting the entire arrangement. For this purpose, it is connected by its data input D to the data output Q of the flip-flop F7 via a logic AND gate 1648. The second input of the logic AND gate 1648 leads to the reset input 1642, to which the control signal Vm is applied in order to start a measurement of the counter 16.

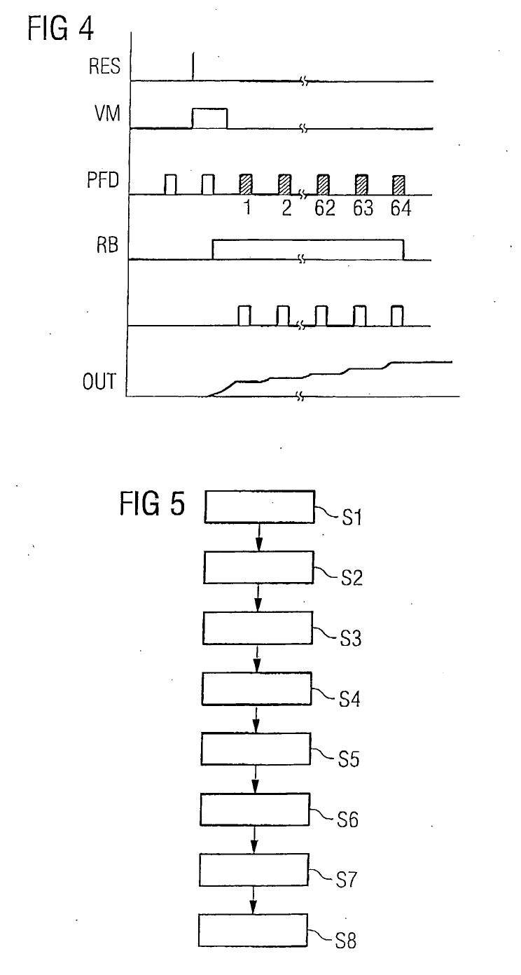

FIG. 4 shows some selected signals which are output during a calibration for determining the frequency and phase drift. The reset signal RES serves for setting and resetting the counter 16. During operation of the control loop, upon rising clock edges of a pulse of the actuating signal PFD, the state of the inverted data output Q′ that is fed to the data input D is applied to the data output Q. With the next rising clock edge of a pulsed signal of the actuating signal PFD, the data output Q of the first flip-flop F1 is inverted again and a logic high state is now output at the data output Q of the second flip-flop F2.

With each rising clock edge of a pulsed signal PFD at the input 1641, the state of the data input is accepted into the next flip-flop of the shift register. After 64 clock cycles, a logic high state is present at the data output Q of the last flip-flop F6. Said state is forwarded to the data output D of the flip-flop F7 by the OR gate 1649. Upon the next falling clock edge, this state at the input D likewise provides a logic high value at the output Q of the flip-flop F7. The inverted output Q′ of the flip-flop F7 simultaneously falls to a logic low state.

In order to start a measuring operation, then, after a reset signal RES at the input 160 of the counter 16, the actuating signal Vm is fed into the input 1642 of the shift register. Since logic high states are then in each case present at both inputs of the AND gate 1648, the gate 1648 passes on a logic high state to the input D of the flip-flop F8. Upon the succeeding next falling clock edge, all flip-flops of the shift register 164 are reset. A logic high state in the output signal RB is thereby produced at the inverting output of the flip-flop F7.

Upon the next rising pulse edge of the actuating signal PFD, two high states are then present at the AND gate 166. As a result, the counter 16 is activated and ascertains the number of clock periods of the output signal of the voltage controlled oscillator 12. At the same time, in the shift register 164, the state is accepted into the first flip-flop F1. Upon the falling clock edge of the pulsed signal PFD, the logic AND gate 166 is inhibited again and the counter 16 is deactivated until the next rising pulse edge.

At the same time, at the output 1644 of the shift register 164, a logic high state in the signal LSB is output and fed to the XOR gate 165. As a result, the polarity of the output signal of the XOR gate is inverted. Upon the next actuating pulse of the actuating signal PFD, counting is effected anew.

The output signal OUT of the counter 16 clearly shows how the entire number of pulses increases during the pulses of the actuating signal PFD, while the number of clock periods ascertained remains the same between the pulses.

The counting operation with regard to the output periods of the voltage controlled oscillator 12 is repeated. After the 63rd repetition, a logic high signal is present again at the data output Q of the flip-flop F6, which is passed on to the data output DE of the flip-flop F7 by the OR gate 1649 and leads to a deactivation of the signal RB upon the next falling clock edge. The counting operation is then concluded. The measured number of clock cycles of the voltage controlled oscillator can then be stored in a register 18 or 18A. The 64 measurements in total do not take a long time, so that during this period of time the drift may be regarded as essentially constant.

The same operation is then repeated at a later point in time at which the drift in the output signal of the oscillator has almost completely disappeared. The second counting operation usually produces significantly fewer clock periods. Since both the time difference between the two measurements and the number of clock cycles in the output signal of the voltage control oscillator are known, the drift and its exponential behavior can be calculated. As a result, it is possible to provide a corresponding correction for a later modulation of the phase locked loop.

FIG. 5 shows an exemplary aspect embodiment of the method according to the invention such as may be carried out for example in a phase locked loop in accordance with FIG. 3.

While, for purposes of simplicity of explanation, the method is depicted and as executing serially. It is to be understood and appreciated that the present invention is not limited by the illustrated order, as some aspects could, in accordance with the present invention, occur in different orders and/or concurrently with other aspects from that depicted and described herein. Moreover, not all illustrated features may be required to implement a methodology in accordance with an aspect the present invention.

In a first step S1, a phase locked loop is provided, and the voltage controlled oscillator is activated. At the same time, a target frequency is prescribed, said frequency having a value of 4.004 GHz, by way of example. The multi-modulus divider 13 is set with a corresponding frequency divider ratio, for example, an integral divider ratio without fractional divider factors. The phase locked loop is supplied with voltage.

In step S2, after a short time, for example in a few 10 μs, the phase locked loop is closed in order to give the capacitances of the loop filter time for a charging operation. During this period of time, the additional dividers 14 and 15 are not yet active, and the reference frequency as well as the fed-back frequency are applied directly to the inputs of the phase comparator.

After a further 20 μs, in step S3, the switches 142 to 154 are closed and the frequency of the reference signal and also the frequency of the fed-back signal are reduced by a fixed, predetermined divider ratio by means of the dividers 14 and 15. The divider ratio in the dividers 14 and 15 for example, has the value 32. A reference frequency of 26 MHz is accordingly divided down to 812.5 kHz.

Step S4 involves waiting until the phase locked loop has changed to the desired frequency of 4.004 GHz. The time duration for setting the phase locked loop to the desired output frequency is approximately 230 μs.

The above-described measurement is then carried out in step S5. As a result of the additional frequency division of the reference signal and of the fed-back signal, the pulse length per actuating pulse of the phase comparator becomes longer by the frequency divider factor set, by the factor 32 in the present case. This allows the counter enough time to measure the clock cycles of the output signal of the oscillator. By means of the shift register, the counting operation is repeated 64-fold, that is to say the clock periods in the output signal of the oscillator are counted in 64 successive actuating pulses. The measurement takes approximately 80 μs.

Afterward, step S6 involves waiting until the drift has almost completely disappeared. Owing to the exponential falling behavior of the frequency and phase drift, the latter has almost completely disappeared after 1 ms. In step S7, the time duration is then determined anew by ascertaining the clock periods of the output signal of the oscillator.

In the final step S8, the drift is calculated by forming the difference between the two measurements, the difference being directly proportional to the drift.

The present method and also the present arrangement are can be advantageous if the length of a pulse of the actuating signal PFD is directly proportional to the frequency deviation of the voltage signal of the oscillator. As a result, the pulse length is also directly proportional to the present frequency drift of the oscillator. Since a deviation of the duty cycle or of the pulse length is only very small on account of the drift at a relatively high reference frequency, it is expedient for the frequency of the reference signal and also the frequency of the fed-back signal to be divided again. This increases the corresponding pulse length of the phase comparator on account of the phase shifts between reference and fed-back signal, as a result of which this time difference can be determined significantly more simply.

After the drift has been determined, it can be taken into account in the direct modulation in order to compensate for phase and frequency errors in the output signal of the oscillator on account of fast frequency jumps. In addition to a direct temporal determination of the pulse lengths at the two different instants, in the present case this time measurement is carried out by means of a counting operation with regard to the clock cycles of the output signal of the oscillator. This is expedient particularly when the output signal of the oscillator has a significantly lower clock period than is represented by the temporal deviation on account of the drift.

The present embodiment may be used directly in an integrated circuit in a semiconductor body. It affords the possibility of determining the drift even during operation at a later point in time and thereby of providing a corresponding compensation for phase or frequency errors of the phase locked loop.

While the invention has been illustrated and described with respect to one or more implementations, alterations and/or modifications may be made to the illustrated examples without departing from the spirit and scope of the appended claims. In particular regard to the various functions performed by the above described components or structures (assemblies, arrangement, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

### LIST OF REFERENCE SYMBOLS

1: Circuit arrangement
2: Reference input
3: Signal output
10a: Phase comparator
10b: Charge pump
11: Loop filter
12: Voltage controlled oscillator
13: Multi-modulus divider
14, 15: Frequency divider
16: Counter
17: Computing unit
18, 18A: Register
101: Reference input
102: Feedback input
104: Actuating output
122: Signal output
131: Signal input
161: Counting input
162: Counting output
164: Shift register
165: XOR gate
166: AND gate
142, 144, 152, 154: Switch
1641: Actuating input
1642: Reset input
1643, 1644: Output
F1, . . . , F8: Flip-flops
D: Data input
Q, Q′: Data output
REF: Reference signal
RES: Reset signal
VM: Reset signal
LSB, RB: Control signal
PFD: Actuating signal

What is claimed is:

1. A circuit arrangement for determining frequency drift comprising:
a phase locked loop comprising:
a reference signal input that receives a reference signal;
a signal output;
a phase comparator having a first input connected to the reference signal input, a feedback input, and an actuation output that outputs an actuating signal;
an oscillator having an oscillator signal output connected to the signal output and an input that receives the actuating signal; and
a frequency divider coupled to the oscillator signal output and the feedback input of the phase comparator;
a device coupled to the phase locked loop that determines a first pulse length from the actuating signal and at least one temporally succeeding pulse length from the actuating signal; and
a computer unit that forms a difference between the first pulse length and the at least on temporally succeeding pulse length.

2. The circuit arrangement of claim 1, wherein the phase locked loop further comprises a charge pump that receives the actuating signal from the phase comparator and generates a voltage signal according to the actuating signal and a loop filter and provides the voltage signal as the actuating signal to the oscillator.

3. The circuit arrangement of claim 1, wherein the device comprises a counter.

4. The circuit arrangement of claim 1, wherein the device comprises a circuit that receives the actuating signal and a counter connected to the circuit, wherein the circuit changes the actuating signal provided by the oscillator according to a control signal.

5. The circuit arrangement of claim 4, wherein the circuit is comprised of a logic XOR gate, wherein a first input is connected to the singal output of the oscillator and a second input is connected to the control signal and the output is connected to the counter.

6. The circuit arrangement of claim 4, wherein the counter comprises at least one activation input for feeding in a pulsed activation signal.

7. The circuit arrangement of claim 6, wherein the activation input comprises a first terminal connected to the first input of the phase comparator and a second terminal coupled to the feedback input of the phase comparator.

8. The circuit arrangement of claim 7, wherein the counter performs a counting operation upon an occurrence of a signal clock edge at one of the first input and the feedback input of the phase comparator until an occurrence of another signal clock edge at an other of the one of the first nput and the feedback input.

9. The circuit arrangement of claim 1, wherein the device comprises a shift register.

10. The circuit arrangement of claim 9, wherein the shift register comprises a number of feedback flip-flops connected in series.

11. The circuit arrangement of claim 9, wherein the device further comprises a circuit and wherein the shift register has a tap at a data output of a first flip-flop that generates a control signal for the circuit.

12. The circuit arrangement of claim 1, further comprising a second frequency divider connected to the reference signal input that initially operates on the reference signal and a third frequency divider connected to the feedback input of the phase comparator and an output of the frequency divider.

13. The circuit arrangement of claim 12, wherein the second frequency divider and the third frequency divider have programmable frequency divider ratios.

14. A circuit arrangement, comprising:
a phase locked loop having a reference signal input that receives a reference signal, a feedback input that receives a feedback signal, and a signal output for providing an actuating signal;
a first means for determining a first pulse length and a second pulse length of the actuating signal generated by the phase locked loop, at two successive times; and
a second means for forming a difference between the first pulse length and the second pulse length.

15. The circuit arrangement as claimed in claim 14, wherein the first means is embodied for detecting clock edges of the reference signal and the feedback signal at the reference signal input and the feedback input of the phase locked loop.

16. A circuit arrangement for determining frequency drift comprising:
a phase locked loop comprising:
a reference signal input;
a signal ouput;
a phase comparator having a first input connected to the reference signal input, a feedback input, and an output that provides an actuating signal;
an oscillator comprising an output coupled to the signal output and to the feedback input of the phase comparator via a frequency divider;
a counter coupled to the signal output of the phase locked loop that detects clock cycles for a predetermined time period in at least two different times; and
a computing unit, connected to an output of the counter that ascertains a frequency drift according to the detected clock cycles.

17. A method for determining frequency drift comprising:
providing a phase locked loop having a charge pump for setting a frequency of an output signal of a voltage controlled oscillator;
providing a reference signal to the phase locked loop;
comparing the output signal with the reference signal;
generating a pulsed actuating signal that sets an operating cycle of the charge pump of the phase locked loop;
measuring a first time duration of the operating cycle of the charge pump of the phase locked loop at a first instant;
measuring a second time duration of the operating cycle of the charge pump of the phase locked loop at a second instant; and
determining a frequency drift according to the measured first time duration and the measured second time duration.

18. The method of claim 17, wherein measuring the first time duration comprises ascertaining a number of clock cycles of the output signal of the oscillator.

19. The method of claim 17, wherein measuring the first time duration and the second time duration comprises ascertaining a number of clock cycles of the output signal of the oscillator during a time between an occurance of a clock edge of the reference signal and a clock edge of a fed-bak frequency divided output signal from the oscillator.

20. The method of claim 17, wherein measuring the first time duration and the second time duration comprises ascertaining a number of clock cycles of the output signal of the oscillator during an occurrence of the pulsed actuating signal.

21. The method of claim 17, wherein generating the pulsed actuating signal comprises:
generating a pulse having a pulse length according to the determined frequency drift; and
providing the pulse to the charge pump.

22. The method of claim 17, wherein providing the reference signal comprises:
dividing a frequency of the reference signal by a predetermined divider factor; and
dividing a frequency of the output signal of the oscillator by the predetermined divider factor.
